(19) United States
(12) Patent Application Publication
(10) Pub. No.: US 2006/0141773 A1
(43) Pub. Date: Jun. 29, 2006

(54) Method of forming metal line in semiconductor device

(76) Inventor: Yung Pil Kim, Icheon-city (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/321,119

(22) Filed: Dec. 28, 2005

(30) Foreign Application Priority Data
Dec. 29, 2004 (KR) 10-2004-0114861

(51) Int. Cl. H01L 21/4763

(52) U.S. Cl. 438/637

(57) ABSTRACT

A method of forming a metal line in a semiconductor device reduces production costs through a simplified fabricating process. The method includes steps of forming a first metal line on a semiconductor substrate; forming an insulating layer over the semiconductor substrate including the first metal line; coating a photoresist on the insulating layer; aligning a diffraction mask having regions or patterns differing from each other in transmittance over the photoresist; patterning the photoresist by exposure and development using the diffraction mask to form a patterned photoresist having regions that differ in thickness; forming a via hole and a trench by etching the patterned photoresist and the insulating layer simultaneously to expose a prescribed portion of the first metal line; removing the remaining photoresist; and forming a second metal line and a contact in the trench and the via hole.

This application claims the benefit of Korean Patent Application No. 10-2004-0114861, filed on Dec. 29, 2004, which is hereby incorporated by reference as if fully set forth herein.

### BACKGROUND OF THE INVENTION

1. Field of the Invention

The present invention relates to a semiconductor device, and more particularly, to a method of forming a metal line in a semiconductor device. Although the present invention is suitable for a wide scope of applications, it is particularly suitable for reducing a product cost and for simplifying a process for forming a dual damascene metal line in a semiconductor device.

2. Discussion of the Related Art

Aluminum and aluminum alloys, which exhibit good electrical conductivity and excellent adhesion with an oxide film and facilitate patterning and layer formation, are widely used materials in the manufacture of a semiconductor device. These materials, however, can have problems in electro-migration, hillocks, and spiking.

In electro-migration, as current flows in the aluminum metal line, atoms of the aluminum are slowly diffused in high-current-density regions such as a stepped region or a contact region with silicon. Over time, the electro-migration causes a thinning of a metal line in the aforementioned regions, and opens or disconnections may occur as a result. Electro-migration can be mitigated by alloying the aluminum with copper, reducing the step size, or enlarging the contact regions.

Spiking generally occurs at the contact regions and is caused as silicon atoms migrate into an aluminum thin film during annealing, and an excessive reaction at a localized area can destroy a device. Such migration can be impeded or stopped by forming the metal line of an aluminum-silicon alloy, with the added silicon being at a level or content above the solubility of Si in Al, or by providing a diffusion barrier, i.e., a thin metal layer of titanium nitride (TiN), titanium-tungsten (TiW) or platinum silicide (PtSi) between an aluminum metal line and the silicon of the contact region.

Development of a substitute material for the aluminum metal line has been conducted. Examples of the substitute material include copper, gold, silver, cobalt, chromium, and nickel, which all exhibit excellent conductivity. Among these, copper and copper alloys are widely used due to their low specific resistance, excellent reliability in terms of electro-migration and stress migration, and lower cost. Metal lines of copper and copper alloys are formed by, for example, depositing copper over a dual damascene structure in an insulator. The dual damascene structure generally includes a via (contact hole) and a trench. The metal lines are produced by simultaneously forming a plug in the via hole and a metal line in the trench, with excess copper being removed from the surface of the wafer by chemical-mechanical polishing. Copper is easily oxidized by and dissolved into the chemical-mechanical polishing slurry. However, copper is known as a metal that is difficult to planarize.

FIGS. 1A-1E illustrate a method of forming a dual damascene metal line in a semiconductor device according to a related art.

Referring to FIG. 1A, a first insulating layer 12 is formed on a semiconductor substrate 11. A first conductive layer is formed on the first insulating layer 12. The first conductive layer is selectively etched by photolithography to form a first metal line 13. A second insulating layer 14 is formed over the semiconductor substrate 11 including the first metal line 13. A first photoresist 15 is coated on the second insulating layer 14.

Referring to FIG. 1B, the first photoresist 15 is selectively patterned by exposure and development to define a contact area (or via hole). The second insulating layer 14 is selectively etched using the patterned first photoresist 15 as a mask to expose a predetermined portion of a surface of the first metal line 13. Hence, a via hole 16 is formed.

Referring to FIG. 1C, the first photoresist 15 is removed. A second photoresist 17 is coated over the semiconductor substrate 11. The second photoresist 17 is then patterned by exposure and development to define a line area. A trench 18 having a prescribed depth from a surface is then formed in the insulator 14 by etching the exposed second insulating layer 14 using the patterned second photoresist 17 as a mask.

Meanwhile, an additional step of filing the via hole to protect from inadvertent damage or defects from photolithography in forming the second metal line may be carried out (not shown).

Referring to FIG. 1D, the second photoresist 17 is removed. A barrier metal layer 19 and a second conductive layer 20 are sequentially formed over the semiconductor substrate 11 including the trench 18 and the via hole 16. The second conductive layer 20 generally comprises copper, which may be deposited into the trench 18 and the via hole 16 by electrochemical plating.

Referring to FIG. 1E, chemical-mechanical polishing is carried out on the semiconductor substrate 11. Hence, the second conductive layer 20 and the barrier layer 19 are removed from areas outside the via hole 16 and the trench 18, and they remain within the via hole 16 and the trench 18, to form a second metal line 20a and a via contact 20b.

In forming a dual damascene metal line, however, the related art method carries out the photolithography process twice to form the via hole and the trench, respectively. Moreover, the related art method may carry out the additional step of filling the via hole with photoresist for protection against problems from photolithography for forming the copper line, increasing the potential for errors to occur.

### SUMMARY OF THE INVENTION

Accordingly, the present invention is directed to a method of forming a metal line in a semiconductor device that substantially obviates one or more problems and/or that overcomes one or more limitations and/or disadvantages of the related art.

An object of the present invention is to provide a method of forming a metal line in a semiconductor device, in which a via hole and trench are simultaneously formed to simplify a fabricating process and lower production costs accordingly.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure(s) and/or process(es) particularly pointed out in the written description and claims hereof as well as the appended drawings.

To achieve these objects and other advantages in accordance with the purpose of the invention, as embodied and broadly described herein, there is provided a method of fabricating a semiconductor device, the method comprising forming a first metal line on a semiconductor substrate; forming an insulating layer over the semiconductor substrate including the first metal line; coating a photoresist on the insulating layer; aligning a diffraction mask having patterns differing from each other in transmittance over the photoresist; patterning the photoresist by exposure and development using the diffraction mask to form a patterned photoresist having regions of different thicknesses; forming a via hole and a trench by etching the patterned photoresist and the insulating layer simultaneously to expose a surface portion of the first metal line and form a trench; removing the remaining photoresist; and forming a second metal line and a contact in the trench and the via hole.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A-1E are cross-sectional diagrams of a semiconductor device in which a metal line is formed according to a related art dual damascene process; and

FIGS. 2A-2E are cross-sectional diagrams of a semiconductor device in which a metal line is formed according to an exemplary method of the present invention.

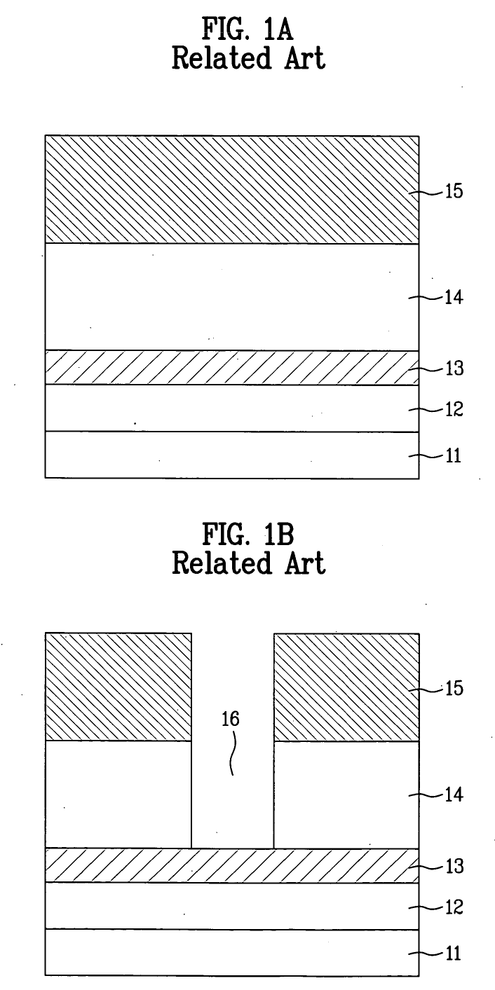

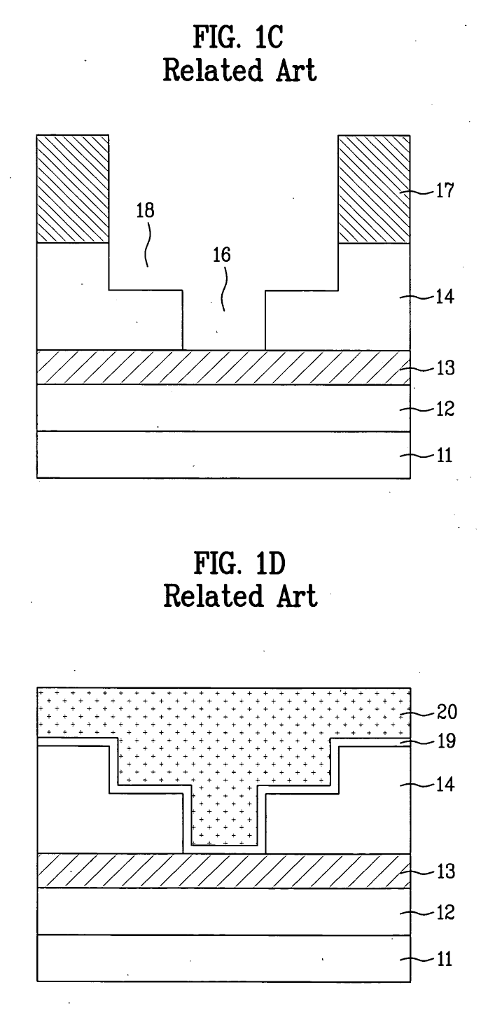

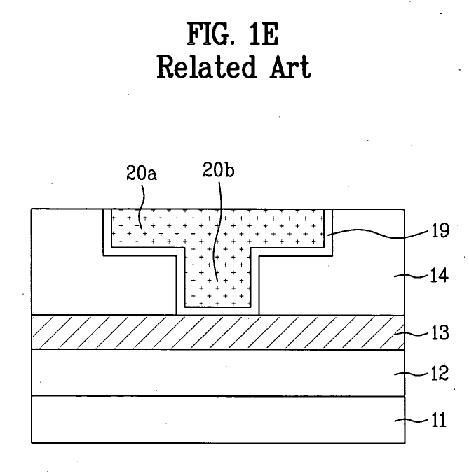

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

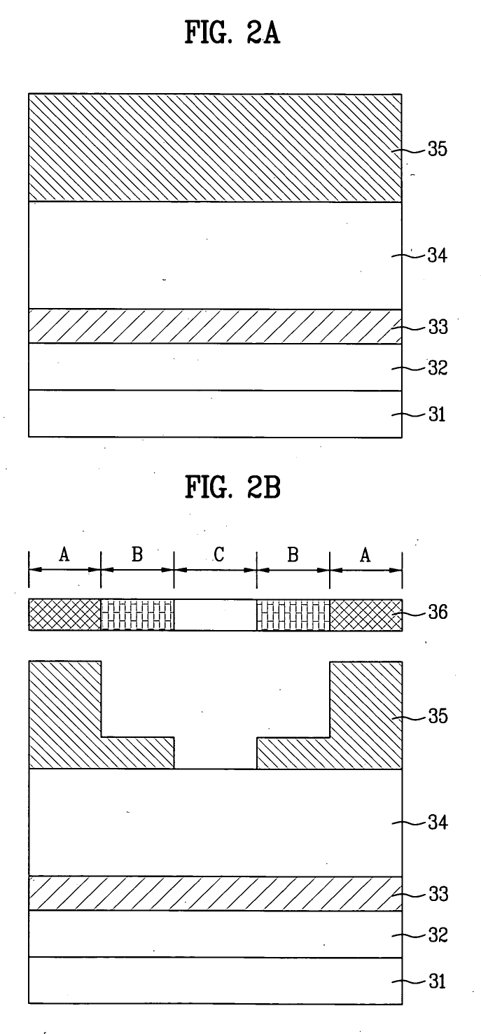

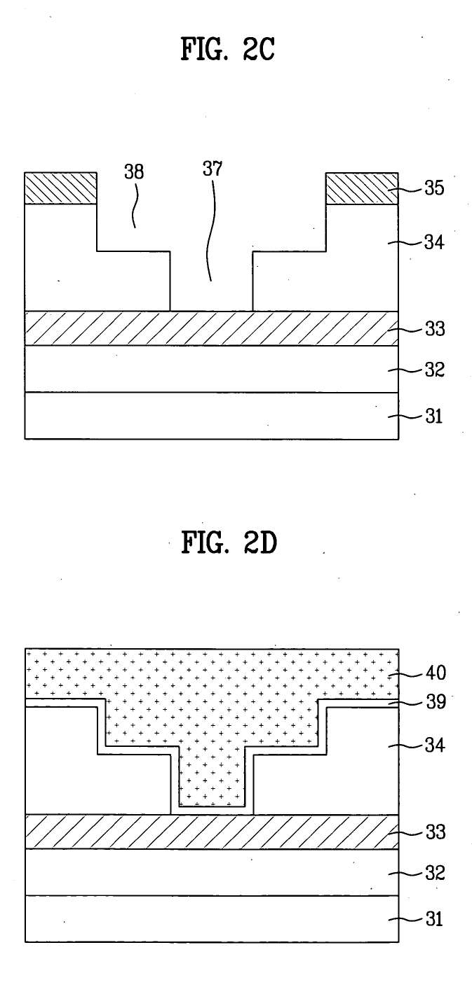

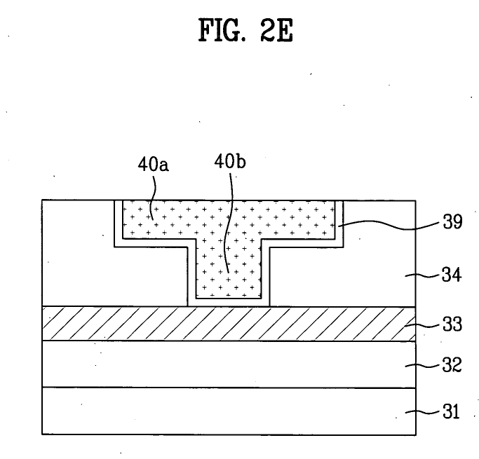

FIGS. 2A-2E illustrate a method of forming a metal line in a semiconductor device according to the present invention.

Referring to FIG. 2A, a first insulating layer 32 is formed on a semiconductor substrate 31. A first conductive layer is formed on the first insulating layer 32. The first conductive layer is patterned by photolithography and selectively etched to form a first metal line 33 (or a plurality of first metal lines 33 in a first metal level of the semiconductor device). Alternatively, the first metal line 33 may be formed by a dual damascene method or by a single damascene method (to form either a metal line in a trench or a metal contact in a via hole), as is known in the art. A second insulating layer 34 is formed over the semiconductor substrate 31 including the first metal line 33. A photoresist 35 is coated on the second insulating layer 34.

The second insulating layer 34 may comprise one or more layers of fluorine-doped silicate glass (FSG), undoped silicate glass (USG) and/or an oxide of phosphorus-doped silicon tetrahydride (P—SiH₄). That is, the second insulating layer 34 may comprise a low-k material to obtain low parasitic capacitance. The second insulating layer 34 may be about twice as thick as a second metal line, to enhance a process margin and insulating characteristics.

FIG. 2B shows a diffraction mask 36 that includes a light shield region A for completely blocking light transmission, a slit part or region B permitting the transmission of a predetermined quantity (or percentage) of light, and an aperture C permitting a full transmission of light. The diffraction mask 36 is aligned over the photoresist 35, which is then irradiated with light of a predetermined wavelength or wavelength band from a light source. Thus, a portion of the photoresist 35 corresponding to the light shield A receives no light, a portion corresponding to the slit part B receives a partial exposure, and a portion corresponding to the aperture C receives a full exposure, so that a pattern is formed by developing the exposed photoresist 35. Here, the A portion of the photoresist 35 remains intact, the B portion is reduced to a predetermined thickness, and the C portion is completely removed.

Namely, in the present invention, the exposure is carried out using the diffraction mask 36 having different transmittances in its line and via hole defining parts. Although the transmittance in the line-defining regions of the diffraction mask 36 can be determined empirically by those skilled in the art using the present disclosure, in general, the transmittance in the line-defining regions of the diffraction mask 36 can be from 20%, 30%, or 40% of the transmittance in the via hole-defining regions of the diffraction mask 36, up to 60%, 70%, or 80% of the transmittance in the via hole-defining regions.

Referring to FIG. 2C, a via hole 37 and a trench 38 are simultaneously formed by anisotropically etching the patterned photoresist 35 and the second insulating layer 34, to expose a predetermined portion of a surface of the first metal line 33. Generally, the predetermined or exposed portion of the first metal line 33 corresponds to the via hole in the insulating layer and the contact portion of the subsequently formed dual damascene metal line. A mask including a via hole defining portion and a trench defining portion having transmittance lower than that of the via hole defining portion is used as the diffraction mask 36 for forming patterned photoresist 35.

Namely, in the present invention, the via hole 37 and the trench 39 are formed by etching, using an etch selection ratio between the second insulating layer 34 and the photoresist 35.

For instance, if a thickness of the second insulating layer 34 is t1, a specific or target thickness of a line is t2, and an etch selection ratio between the photoresist 35 and the second insulating layer 34 is 1:s, a thickness T of the photoresist remaining in the portion or region where the trench 38 will be formed is preferably (t1−t2)/s. More preferably, the thickness T may be increased by a small amount (e.g., 3-10%) to provide a sufficient etch margin for formation of the via hole 37.

Referring to FIG. 2D, the remaining photoresist 35 is removed. A barrier metal layer 39 is deposited over the semiconductor substrate 31 including the via hole 37 and the trench 38. In doing so, the barrier metal layer 39 may comprise or consist essentially of TiN, Ta, TaN, WNₓ, TiAl(N), or the like to a thickness of 10˜1,000 Å by physical or chemical vapor deposition. The barrier metal layer 39 plays a role in preventing copper atoms of a copper film from diffusing into the second insulating layer 34.

A second conductive layer 40 is formed on the barrier metal layer 39 by, for example, sputtering, physical vapor deposition, or chemical vapor deposition of copper, aluminum, platinum, or an alloy of any of these. For a second conductive layer 40 of copper, for instance, a copper film is formed by electroplating after forming a Cu seed layer on the barrier metal layer 39, with the Cu seed layer being formed by a stable and clean deposition process such as PVD, sputtering, or (in some cases) CVD.

After a diffusion barrier layer and a Cu seed layer have been deposited using a physical vapor deposition or chemical vapor deposition chamber, copper-electroplating can be carried out. Here, the copper is deposited on the Cu seed layer by metal-organic chemical vapor deposition (without breaking vacuum after seed layer formation, if the seed layer is also deposited by CVD) or by electroplating, at a temperature of −20˜150° C.

Referring to FIG. 2E, chemical-mechanical polishing is carried out over the semiconductor substrate 31 (i.e., portions of the second conductive layer 40 and the barrier metal layer 39 are removed from outside the via hole 37 and the trench 38 by chemical-mechanical polishing). Hence, the second conductive layer 40 and the barrier metal layer 39 remain within the via hole 37 and the trench 38 only to form a second metal line 40a and a via contact 40b.

By simultaneously forming the via hole and the trench using an etch selection ratio between the insulating layer and the photoresist, the present invention can reduce the product cost, increase the throughput of the devices and simplify the fabrication process. In addition, by simplifying the fabrication process to lower the number of possible sources of process errors, the present invention can raise the yield of the devices.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A method of fabricating a semiconductor device, comprising:
patterning a photoresist on an insulating layer over a semiconductor substrate including a first metal line by exposure and development using a diffraction mask having regions of different transmittance to form a patterned photoresist having regions that differ in thickness;
forming a via hole and a trench by etching the patterned photoresist and the insulating layer simultaneously to expose a portion of a surface of the first metal line;
removing the remaining photoresist; and
forming a second metal line and a contact in the trench and the via hole.

2. The method of claim 1, further comprising the step of forming a barrier metal layer in the via hole and the trench.

3. The method of claim 1, wherein the insulating layer comprises a low-k material.

4. The method of claim 3, wherein the low-k material comprises fluorine-doped silicate glass, undoped silicate glass and/or an oxide of phosphorus-doped silicon tetrahydride (P—SiH₄).

5. The method of claim 1, wherein the insulating layer has a thickness at least twice that of the second metal line.

6. The method of claim 1, wherein the diffraction mask comprises a shielding region adapted to shield light, a transmitting region or aperture adapted to transmit light, and a slit region having a reduced transmittance, adapted to transmit part of the light.

7. The method of claim 1, wherein a thickness of the photoresist remaining in a trench-defining area is equal to or greater than (t1−t2)/s, where t2 is a thickness of the second metal line, t1 is a thickness of the insulating layer, and s is an etch selection ratio of the insulating layer relative to the photoresist.

8. The method of claim 1, further comprising aligning the diffraction mask over the photoresist.

9. The method of claim 1, further comprising coating the photoresist on the insulating layer.

10. The method of claim 9, further comprising forming the insulating layer over the semiconductor substrate including the first metal line.

11. The method of claim 10, further comprising forming the first metal line on the semiconductor substrate.

12. The method of claim 1, wherein the second metal line comprises copper.

13. The method of claim 12, further comprising the step of forming a barrier metal layer comprising TiN, Ta, TaN, WNₓ, or TiAl(N) in the via hole and the trench.

14. The method of claim 12, wherein forming the copper film comprises electroplating.

15. The method of claim 13, further comprising the step of forming a copper seed layer on the barrier metal layer.

16. The method of claim 12, wherein forming the copper seed layer comprises PVD, sputtering, or CVD.

17. The method of claim 1, wherein the exposed portion of the first metal line corresponds to the via hole in the insulating layer and the contact.

18. The method of claim 1, wherein a line-defining region of the diffraction mask has a transmittance of from 20% to 80% of a transmittance in a via hole-defining region of the diffraction mask.
